(19) United States
(12) Patent Application Publication
(10) Pub. No.: US 2013/0178010 A1
(43) Pub. Date: Jul. 11, 2013

(54) METHOD OF FORMING A METAL PATTERN AND METHOD OF MANUFACTURING A DISPLAY SUBSTRATE

(71) Applicants: Bong-Kyun KIM, Hwaseong-si (KR); Wang-Woo Lee, Suwon-si (KR); Shin Il Choi, Hwaseong-si (KR); Hong-Sick Park, Suwon-si (KR); Young-Woo Park, Seongnam-si (KR)

(72) Inventors: Bong-Kyun KIM, Hwaseong-si (KR); Wang-Woo Lee, Suwon-si (KR); Shin Il Choi, Hwaseong-si (KR); Hong-Sick Park, Suwon-si (KR); Young-Woo Park, Seongnam-si (KR)

(21) Appl. No.: 13/585,255

(22) Filed: Aug. 14, 2012

(30) Foreign Application Priority Data
Jan. 9, 2012 (KR) 2012-0002502

(51) Int. Cl. C23F 1/14; B05D 3/00; H01L 33/08

(52) U.S. Cl. 438/73; 427/259; 216/41; 257/E33.053

(57) ABSTRACT

A method of forming a metal pattern is provided. In the method, a first titanium layer, a copper layer and a second titanium layer are sequentially formed on a substrate. A photo pattern is formed on the second titanium layer. The first titanium layer, the copper layer and the second titanium layer are patterned using the photo pattern to form a first titanium pattern, a copper pattern formed on the first titanium pattern and a second titanium pattern formed on the copper pattern. Therefore, a fine metal pattern may be formed.

### CROSS-REFERENCE TO RELATED APPLICATION

This application claims priority under 35 U.S.C. §119 to Korean Patent Application No. 2012-0002502, filed on Jan. 9, 2012, the disclosure of which is hereby incorporated by reference herein in its entirety.

### 1. TECHNICAL FIELD

Example embodiments of the present invention relate to a method of forming a metal pattern and a method of manufacturing a display substrate. More particularly, example embodiments of the present invention relate to a method of forming a fine metal pattern and a method of manufacturing a display substrate.

### 2. DISCUSSION OF RELATED ART

A display substrate used in a display device may include, for example, a thin-film transistor (“TFT”) as a switching element for driving a pixel region, a signal line connected to the TFT, and a pixel electrode. The signal line includes a gate line transmitting a gate driving signal and a data line crossing the gate line and transmitting a data driving signal.

As a size of the display device and requirements by customers for higher resolution are increased, a length of the gate line or the data line may be increased and a width of the gate line or the data line maybe decreased so that an electric resistance is increased. Thus, a resistance-capacitance (“RC”) signal delay may be caused. The gate line or the data line may be formed from a metal having a relatively low resistance or the width of the gate line or the data line may be increased to prevent and/or reduce the RC signal delay.

Copper as the metal having a relatively low resistance and used for forming the gate line or the data line may have beneficial electric conductivity and is a natural resource. Copper has a resistance significantly lower than aluminum or chrome.

The thickness of the gate line or the data line may be equal to or greater than about 5,000 Å. To form the gate line or the data line having the thickness equal to or greater than about 5,000 Å, a critical dimension (“CD”) of the gate line or the data line may be required to be increased. To increase the CD, a taper angle of the gate line or the data line may be required to be at least about 60°.

However, there may be a difficulty in that the taper angle of the gate line or the data line may be equal to or less than about 40° by an etching property of a metal layer including copper and an etching composition for etching the metal layer.

### SUMMARY

Example embodiments of the present invention provide a method of manufacturing a metal pattern having a thickness equal to or greater than about 5,000 Å and a fine width by using an etching composition.

Example embodiments of the present invention also provide a method of manufacturing a display substrate including a metal pattern having a thickness equal to or greater than about 5,000 Å and a fine width.

According to an example embodiment of the present invention, a method of forming a metal pattern is provided. In the method, a first titanium layer, a copper layer and a second titanium layer are sequentially formed on a substrate. A photo pattern is formed on the second titanium layer. The first titanium layer, the copper layer and the second titanium layer are patterned using the photo pattern to form a first titanium pattern, a copper pattern formed on the first titanium pattern and a second titanium pattern formed on the copper pattern.

In an embodiment, the copper layer may have a thickness in a range between about 1 μm and about 3 μm.

In an embodiment, the first titanium layer, the copper layer and the second titanium layer may be patterned using an etching composition. The etching composition may include about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water.

In an embodiment, the photo pattern may be removed, and the substrate on which the second titanium pattern, the copper pattern and the first titanium pattern are formed, may washed using a cleaning solution including hydrogen fluoride (HF).

In an embodiment, the copper pattern may have a taper angle between about 60° and about 90°.

According to another aspect of the present invention, a method of manufacturing a display substrate is provided. In the method, a first titanium layer, a first copper layer and a second titanium layer are sequentially formed on a base substrate. A photo pattern is formed on the second titanium layer. The first titanium layer, the first copper layer and the second titanium layer are patterned using the photo pattern, to form a first signal line including a first titanium pattern, a first copper pattern and a second titanium pattern. A second signal line crossing the first signal line is formed, and a pixel electrode is formed. The pixel electrode is connected to a thin-film transistor which is connected to the first and second signal lines.

In an embodiment, wherein the first copper layer may have a thickness in a range between about 1 μm and about 3 μm.

In an embodiment, the first titanium layer, the first copper layer and the second titanium layer may be patterned using an etching composition. The etching composition may include about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water.

In an embodiment, the second signal line may be washed using a cleaning solution including hydrogen fluoride.

In an embodiment, the copper pattern may have a taper angle between about 60° and about 90°.

According to an example embodiment of the present invention, a method for manufacturing a display substrate is provided. The method includes forming a gate metal layer on a base substrate. The gate metal layer includes a first metal layer including titanium disposed on the base substrate, a second metal layer including copper disposed on the first metal layer including titanium, and a third metal layer including titanium disposed on the second metal layer including copper. The method further includes forming a first photo pattern on the gate metal layer, etching the gate metal layer using the first photo pattern to form a gate line and a gate electrode connected to the gate line, and the gate line and the gate electrode include a first metal pattern including titanium, a second metal pattern including copper and a third metal pattern including titanium, and sequentially forming a gate insulating layer, a semiconductive layer, an ohmic contact layer and a source metal layer on the base substrate on which the gate electrode and the gate line are formed. The source metal layer includes a fourth metal layer including titanium, a fifth metal layer including copper formed on the fourth metal layer including titanium and a sixth metal layer including titanium formed on the fifth metal layer including copper.

In addition, the method further includes forming a photoresist layer on the source metal layer, exposing and developing the photoresist layer to form a second photo pattern on the source metal layer, etching the source metal layer using the second photo pattern to form a data line crossing the gate line and a switching pattern connected to the data line. The data line and the switching pattern include a fourth metal pattern including titanium, a fifth metal pattern including copper and a sixth metal pattern including titanium. The etching of at least one of the gate metal layer or the source metal layer is performed using an etching composition which includes ammonium persulfate, an inorganic acid, an acetate salt, a fluorine-containing compound, a sulfonic acid compound, an azole-based compound and water.

Furthermore, the method also includes etching the ohmic contact layer and the semiconductor layer using the second photo pattern and the switching pattern as an etching stop layer, removing a portion of the second photo pattern to form a residual pattern and etching the switching pattern using the residual pattern to form a source electrode connected to the data line and a drain electrode spaced apart from the source electrode.

According to the present invention, a titanium layer is formed on a copper layer to control an etching degree of the copper layer by an etching composition. Thus, a copper pattern having a taper angle equal to or greater than about 60° is formed to realize forming a fine pattern.

### BRIEF DESCRIPTION OF THE DRAWINGS

Example embodiments of the present invention can be understood in more detail from the following detailed description when taken in conjunction with the accompanying drawings in which:

FIG. 1 and FIG. 2 are cross-sectional views illustrating a method of forming a metal pattern according to an example embodiment of the present invention;

FIG. 3A and FIG. 3B are tables including scanning electron microscope (“SEM”) pictures representing an edge portion of Samples 1 to 3 according to an example embodiment of the present invention and Comparative Samples 1 to 3; and

FIG. 4 to FIG. 9 are cross-sectional views illustrating a method of manufacturing a display substrate according to an example embodiment of the present invention.

### DETAILED DESCRIPTION OF EXAMPLE EMBODIMENTS OF THE INVENTION

Hereinafter, example embodiments of the present invention will be explained in detail with reference to the accompanying drawings.

In the drawings, the thickness of layers, films, panels, regions, etc., may be exaggerated for clarity. It will be understood that when an element such as, for example, a layer, film, region, or substrate is referred to as being “on”, “connected to” or “coupled to” another element, it can be directly on, connected to or coupled to the other element or intervening elements may also be present. Like reference numerals designate like elements throughout the specification.

As used herein, the singular forms, “a”, “an”, and “the” are intended to include plural forms as well, unless the context clearly indicates otherwise.

Method of Forming a Metal Pattern

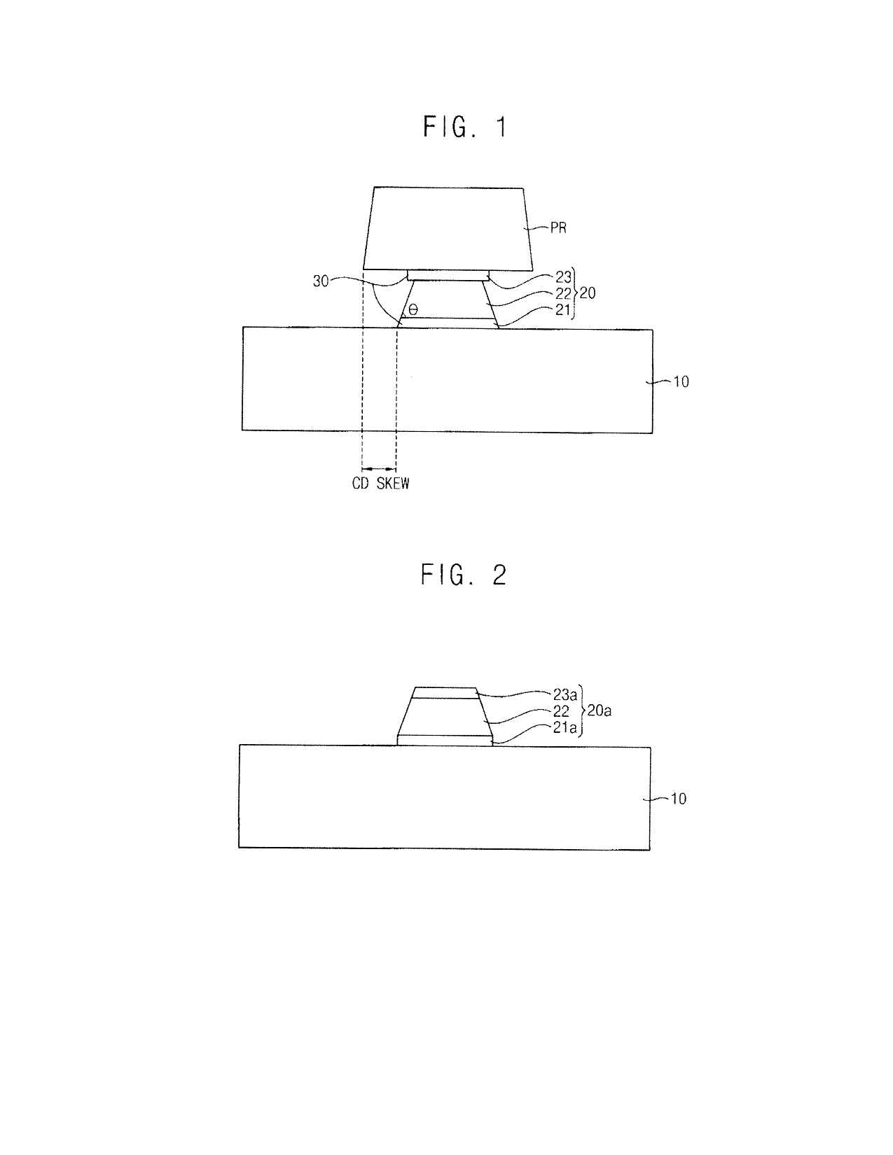

FIG. 1 and FIG. 2 are cross-sectional views illustrating a method of forming a metal pattern according to an example embodiment of the present invention.

Referring to FIG. 1, a metal pattern is formed on a substrate 10, and a photo patter PR is formed on the metal layer. The metal layer may include, for example, a first titanium layer, a copper layer formed on the first titanium layer and a second titanium layer formed on the copper layer. Here, the first and second titanium layers are respectively defined as, for example, a metal layer including titanium and may further include a different metal from titanium as a titanium alloy layer. In addition, the copper layer is defined as, for example, a metal layer including copper and may further include a different metal from copper as a copper alloy layer. The first titanium layer is formed under the copper layer to increase an adhesive strength between the copper layer and the substrate 10. The second titanium layer is formed on the copper layer to increase an etching property of the copper layer. Alternatively, the first titanium layer may, for example, be omitted from the metal layer.

For example, the first titanium layer has a thickness of about 200 Å, and the second titanium layer has a thickness of about 300 Å. The copper layer has a thickness, for example, equal to or greater than about 5,000 Å. For example, the copper layer may have a thickness between about 1 μm and about 3 μm.

The metal layer is etched using the photo pattern PR as an etching stop layer to form a metal pattern 20. Here, the metal pattern 20 may have a fine width, for example, equal to or less than about 0.5 μm.

The metal layer is etched using an etching composition including, for example, about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water.

Ammonium persulfate of the etching composition may function as an oxidizing agent to etch the copper layer. Ammonium persulfate etches the copper layer to generate the reaction represented by the following Reaction Formula 1 to form a stable compound.

S₂O₈⁻²+2Cu→2CuSO₄ <Reaction Formula 1>

Ammonium persulfate may have a desired degree of purity in a semiconductor process. When an amount of ammonium persulfate is less than about 0.1% by weight, the etching of the copper layer may be difficult. When the amount of ammonium persulfate is greater than about 30% by weight, the controlling of a process may be difficult due to an excessive increase of an etching ratio of the copper layer. Thus, the amount of ammonium persulfate may be, for example, about 0.1% by weight to about 30% by weight. For example, the amount of ammonium persulfate may be about 5% by weight to about 25% by weight. In an embodiment, the amount of ammonium persulfate may be, for example, about 10% by weight to about 20% by weight.

The inorganic acid is an assistant oxidizing agent for etching the copper layer. The inorganic acid may prevent reduction of an etching ratio due to copper ions generated in the etching process of the copper layer. Examples of the inorganic acid may include but are not limited to nitric acid, phosphoric acid, sulfuric acid, hydrochloric acid and the like. These can be used alone or in a combination thereof. The inorganic acid may include, for example, nitric acid. The inorganic acid may have a desired degree of purity in a semiconductor process. When an amount of the inorganic acid is less than about 0.1% by weight, its efficiency as an assistant oxidizing agent may be low. When the amount of the inorganic acid is greater than about 10% by weight, an etching ratio of the copper layer may excessively increase to cause disconnection of a signal line. Thus, the amount of the inorganic acid may be, for example, about 0.1% by weight to about 10% by weight. The amount of the inorganic acid may be, for example, about 1% to about 8% by weight. In an embodiment, the amount of the inorganic acid may be, for example, about 2% by weight to about 5% by weight.

The acetate salt may control an etching ratio of the copper layer. The acetate salt may be dissociated to generate an acetic acid ion (CH₃COO⁻). Examples of the acetate salt may include but are not limited to ammonium acetate (CH₃COONH₄), lithium acetate (CH₃COOLi), potassium acetate (CH₃COOK) and the like. These can be used alone or in a combination thereof. The acetate salt may include, for example, ammonium acetate (CH₃COONH₄). The acetate salt may have a desired degree of purity in a semiconductor process. When an amount of the acetate salt is less than about 0.1% by weight, the controlling of an etching ratio may be difficult. When the amount of the acetate salt is greater than about 30% by weight, the etching of the copper layer may be irregular, or the copper layer may not be etched. Thus, the amount of the acetate salt may be, for example, about 0.1% by weight to about 10% by weight. The amount of the acetate salt may be, for example, about 1% by weight to about 8% by weight. In an embodiment, the amount of acetate salt may be, for example, about 2% by weight to about 5% by weight.

The fluorine-containing compound includes fluorine, and etches the first and second titanium layers. Examples of the fluorine-containing compound may include but are not limited to sodium fluoride (NaF), sodium bifluoride (NaHF₂), ammonium fluoride (NH₄F), ammonium bifluoride (NH₄HF₂), ammonium fluoroborate (NH₄BF₄), potassium fluoride (KF), potassium bifluoride (KHF₂), aluminum fluoride (AlF₃), fluoroboric acid (HBF₄), lithium fluoride (LiF), potassium tetrafluoroborate (KBF₄), calcium fluoride (CaF₂) and the like. These can be used alone or in a combination thereof. The fluorine-containing compound may include, for example, ammonium fluoride (NH₄F). When an amount of the fluorine-containing compound is less than about 0.01% by weight, an etching of the titanium layer may be difficult. When the amount of the fluorine-containing compound is greater than about 5% by weight, a glass and an insulation layer disposed below the titanium layer may be etched to cause defects. Thus, the amount of the fluorine-containing compound may be, for example, about 0.01% by weight to about 5% by weight. The amount of the fluorine-containing compound may be, for example, about 0.1% by weight to about 3% by weight. In an embodiment, the amount of the fluorine-containing compound may be, for example, about 0.5% by weight to about 1% by weight.

The sulfonic acid compound includes, for example, a sulfonic acid group (—SO₃H), and prevents decomposition of ammonium persulfate to increase the stability of the etching composition. Examples of the sulfonic acid compound may include but are not limited to methanesulfonic acid (CH₃SO₃H), benzenesulfonic acid (C₆H₅SO₃H), p-toluenesulfonic acid (C₇H₇SO₃H) and the like. These can be used alone or in a combination thereof. The sulfonic acid may include, for example, methanesulfonic acid (CH₃SO₃H). When an amount of the sulfonic acid compound is less than about 0.01% by weight, its efficiency as a stabilizer may be low. When the amount of the sulfonic acid compound is greater than about 5% by weight, the controlling of a process may be difficult due to an excessive increase of an etching ratio of the copper layer. Thus, the amount of the sulfonic acid compound may be, for example, about 0.01% to about 5% by weight. The amount of the sulfonic acid compound may be, for example, about 0.01% by weight to about 3% by weight. In an embodiment, the amount of the sulfonic acid compound may be, for example, about 0.05% by weight to about 1% by weight.

The azole-based compound includes, for example, a pentagonal hetero ring containing a nitrogen atom and at least one atom different from carbon. The azole-based compound may inhibit etching of the copper layer to control an etching ratio difference between the copper layer and the second titanium layer. The azole-based compound may include, for example, benzotriazole, aminotetrazole, aminotetrazole potassium salt, imidazole, pyrazole and the like. These can be used alone or in a combination thereof. The azole-based compound may include, for example, aminotetrazole. When an amount of the azole-based compound is less than about 0.01% by weight, an etching ratio of the copper may not be controlled which in turn may cause excessive CD loss. When the amount of the azole-based compound is greater than about 2% by weight, the etching of the copper layer may be irregular, or the copper layer may not be etched. Thus, the amount of the azole-based compound may be, for example, about 0.01% by weight to about 2% by weight. The amount of the azole-based compound may be, for example about 0.1% by weight to about 1.5% by weight.

The etching composition may further include, for example, about 0.01% by weight to about 5% by weight of a boron-containing compound.

The boron-containing compound includes boron, and may uniformly control an etching ratio of the titanium layer. Examples of the boron-containing compound may include but are not limited to borate (R₁BO₃, R₂HBO₃, R₃H₂BO₃), metaborate (R₃BO₂), tetraborate (R₂B₄O₇, R₃HB₄O₇), ammonium fluoroborate (NH₄BF₄), fluoroboric acid (HBF₄), lithium fluoroborate (LiBF₄), sodium fluoroborate (NaBF₄), potassium fluoroborate (KBF₄) and the like. The above “R₁” represents H₃, Li₃, Na₃, (NH₄)₃ or K₃. The above “R₂” represents Li₁, Na₂, K₂ or (NH₄)₂. The above “R₃” represents Li, Na, K or NH₄. These can be used alone or in a combination thereof. The boron-containing compound may include, for example, fluoroboric acid (HBF₄). When an amount of the boron-containing compound is less than about 0.01% by weight, the controlling of an etching ratio of the titanium layer may be difficult. When the amount of the boron-containing compound is greater than about 5% by weight, the etching of the titanium layer may be difficult. Thus, the amount of the boron-containing compound may be, for example, about 0.01% by weight to about 5% by weight. The amount of the boron-containing compound may include, for example, about 0.05% by weight to about 3% by weight.

The etching composition includes, for example, water with ammonium persulfate, the inorganic acid, the acetate salt, the fluorine-containing compound, the sulfonic acid compound, and the azole-based compound. Examples of water may include but are not limited to pure water, ultrapure water, deionized water, distilled water, and the like. An amount of water may be properly controlled based on the amounts of the etching composition.

The etching composition may stably etch the first and second titanium layers as well as the copper layer. Thus, as a result, the first and second titanium layers and the copper layer may be etched, for example, simultaneously by the etching composition.

The first titanium layer, the copper layer and the second titanium layer are etched to form a metal pattern 20 including a first titanium pattern 21, a copper pattern 22 formed on the first titanium pattern 21, and a second titanium pattern 23 formed on the copper pattern 22.

The metal pattern 20 may be over-etched due to a wet-etching property, compared to a width of the photo pattern PR. Thus, an edge portion of the metal pattern 20 may not coincide with an edge portion of the photo pattern PR. A distance between the edge portions of the metal pattern 20 and the photo pattern PR may be defined as a critical dimension (“CD”) skew.

An adhesive strength between the copper layer and the second titanium layer is greater than that between the copper layer and the photo pattern PR. Thus, an etching degree of the copper layer disposed under the second titanium layer by the etching composition is less than that of the copper layer when the copper layer contacts with the photo pattern PR. The etching composition may readily permeate between the copper layer and the photo pattern, in comparison to between the copper layer and the second titanium layer, so that a taper angle of the copper layer may be increased. Thus, the copper pattern 22 having a large taper angle (θ) is formed by the second titanium layer. For example, the copper pattern 22 may have the taper angle (θ) in a range between about 60° and about 90°.

In addition, a selective etching ratio between the copper layer, the first and second titanium layers are different from each other for the etching composition. A selective etching ratio of the copper layer for the etching composition is larger than that of the first and second titanium layers for the etching composition. Thus, the copper layer may be over-etched, compared to the first and second titanium layers. Therefore, edge portions of the first and second titanium patterns 21 and 23 formed by etching the first and second titanium layers may be protruded compared to an edge portion of the copper pattern 22 by etching the copper layer, so that the first and second titanium patterns 21 and 23 may have a tip 30 protruded from the edge portion of the copper pattern 22.

Referring to FIG. 2, the photo pattern PR is stripped, and the substrate 10, on which the metal pattern 20 including the first titanium pattern 21, the copper pattern 22 and the second titanium pattern 23 is formed, is washed using a cleaning solution. The cleaning solution may include, for example, hydrogen fluoride (HF). For example, the cleaning solution may include a solution diluted by about 300:1 of water and hydrogen fluoride. The metal pattern 20 may be washed, for example, by the cleaning solution for about 90 seconds. Thus, a tip 30 of the first and second titanium patterns 21 and 23 may be removed. In removing the tip 30, an under cut may be generated by washing the first titanium pattern 21 covered by the copper pattern 22. However, the under cut may be ignored.

Therefore, a metal pattern 20a including the copper pattern 22 and the first and second titanium patterns 21a and 23a from which the tip 30 is removed may be formed on the substrate 10.

Hereinafter, a method of forming a metal pattern according to an example embodiment of the present invention will be illustrated with Examples and Comparative Examples in detail.

Metal layers were formed according to Examples 1 to 3 of an example embodiment of the present invention and Comparative Examples 1 to 3 and as the following Table 1.

TABLE 1

| | | | A thickness | A thickness |
|---|---|---|---|---|
| | A stacked | | of a titanium | of a titanium |
| | structure | A thickness | layer disposed | layer disposed |
| | of a metal | of a copper | under the | on the |
| | layer | layer | copper layer | copper layer |
| Example 1 | Ti/Cu/Ti | 1 μm | 200 Å | 300 Å |
| Example 2 | Ti/Cu/Ti | 2 μm | 200 Å | 300 Å |
| Example 3 | Ti/Cu/Ti | 3 μm | 200 Å | 300 Å |
| Comparative | Ti/Cu | 1 μm | 200 Å | — |
| Example 1 | | | | |
| Comparative | Ti/Cu | 2 μm | 200 Å | — |
| Example 2 | | | | |
| Comparative | Ti/Cu | 3 μm | 200 Å | — |
| Example 3 | | | | |

The metal layer according to Example 1 of an example embodiment of the present invention was over-etched by about 60% using an etching composition including about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water to form Sample 1 including a first metal pattern. The metal layer according to Example 2 of an example embodiment of the present invention was over-etched by about 60% using the etching composition to form Sample 2 including a second metal pattern, and the metal layer according to Example 3 of an example embodiment of the present invention was over-etched by about 40% using the etching composition to form Sample 3 including a third metal pattern. Similarly, the metal layers according to Comparative Examples 1 and 2 were over-etched by about 60% using the etching composition to form Comparative Sample 1 including a fourth metal pattern and Comparative Sample 2 including a fifth metal pattern. In addition, the metal layer according to Comparative Example 3 was over-etched by about 40% using the etching composition to form Comparative Sample 3 including a sixth metal pattern. Here, “over-etching” is defined as excessively etching a metal with respect to the end point detection (“EPD”). The EPD defines a time when the metal layer is etched to expose, for example, a glass substrate, a plastic substrate or a ceramic substrate, disposed under the metal layer.

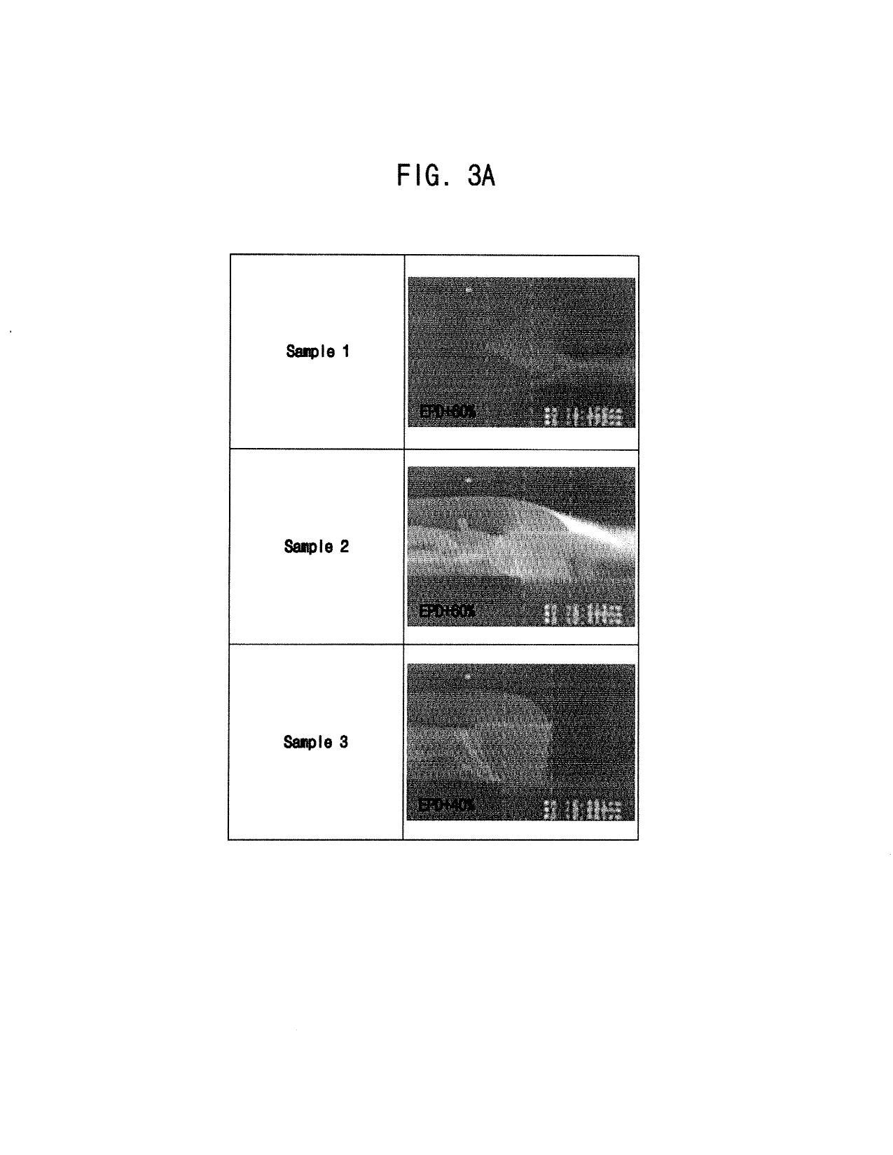

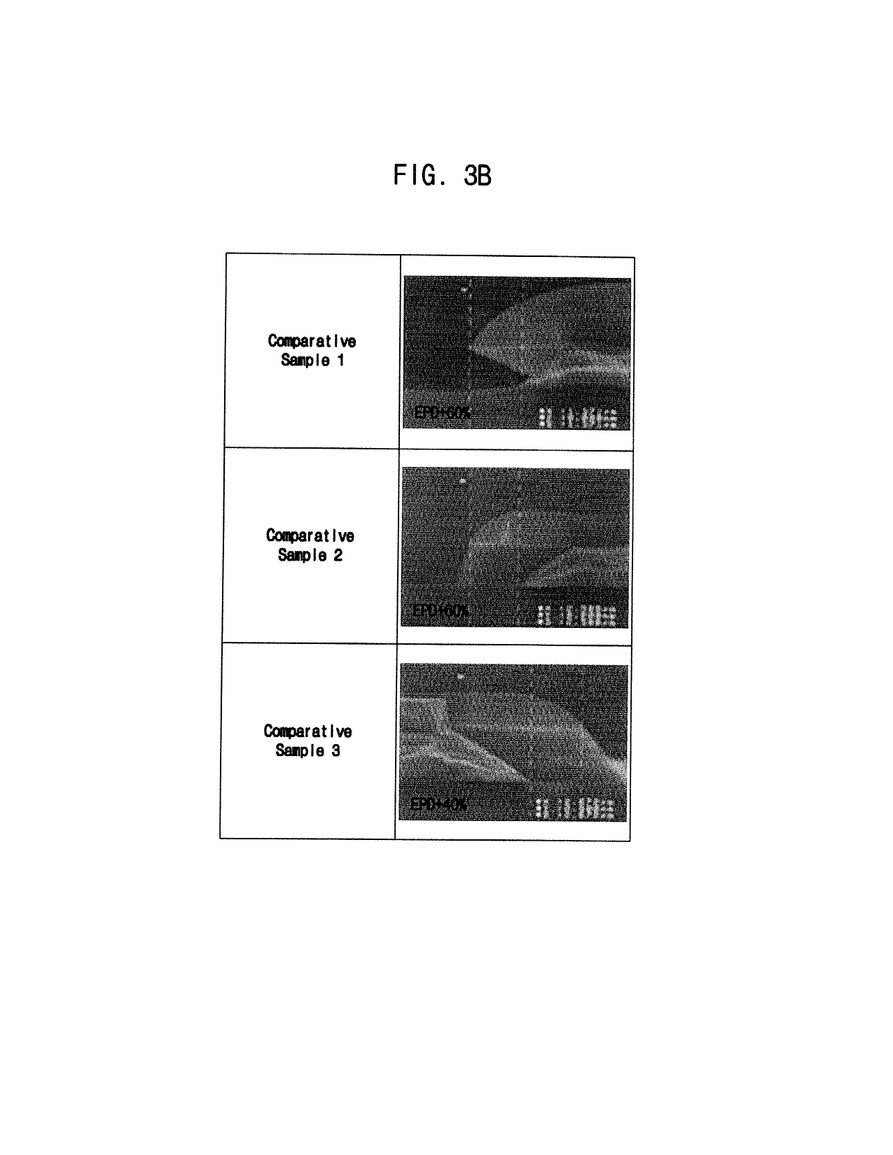

A critical dimension (“CD”) skew and a taper angle of the first to sixth metal patterns in Samples 1 to 3 and Comparative Sample 1 to 3 were measured, and thus obtained results are illustrated in Table 2, FIG. 3A and FIG. 3B.

TABLE 2

| | CD Skew | Taper Angle |
|---|---|---|
| | (μm) | (°) |
| Sample 1 | 1.25 | 61 |
| Sample 2 | 2.42 | 61 |
| Sample 3 | 2.52 | 60 |
| Comparative Sample 1 | 1.26 | 37 |
| Comparative Sample 2 | 2.31 | 32 |
| Comparative Sample 3 | 2.57 | 31 |

In Table 2, the CD skew represents a distance between an edge portion of a photo pattern as an etching stop layer and an edge portion of the metal pattern.

FIG. 3A and FIG. 3B are tables including scanning electron microscope (“SEM”) pictures representing an edge portion of Samples 1 to 3 according to an example embodiment of the present invention and Comparative Samples 1 to 3.

Referring to Table 2 with FIG. 3A and FIG. 3B, the CD skews of the first to third metal patterns formed according to Examples 1 to 3 of an example embodiment of the present invention are substantially the same level as the CD skews of the fourth to sixth metal patterns formed according to Comparative Examples 1 to 3.

However, the taper angles of the first to third metal patterns formed according to Examples 1 to 3 of an example embodiment of the present invention are relatively larger than those of the forth to sixth metal patterns formed according to Comparative Examples 1 to 3.

Method of Manufacturing an Array Substrate

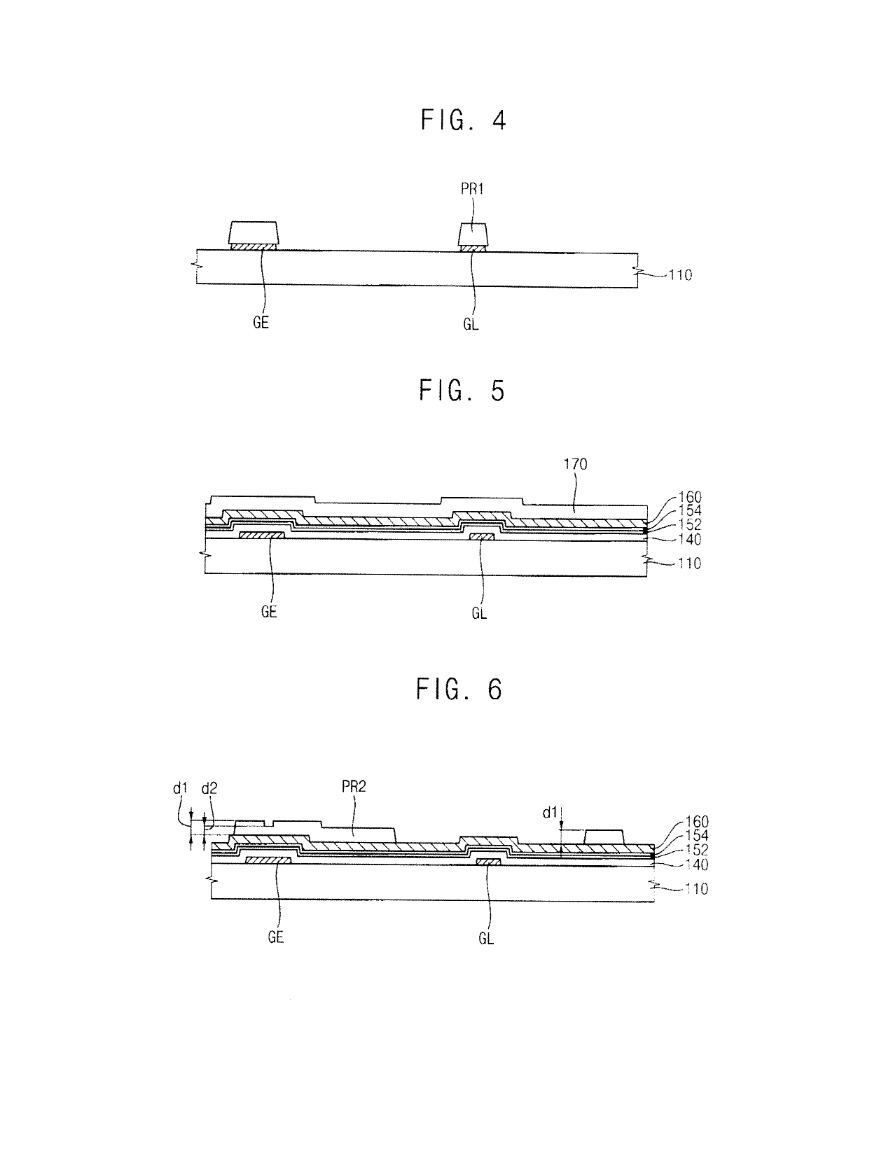

FIG. 4 to FIG. 9 are cross-sectional views illustrating a method of manufacturing a display substrate according to an example embodiment of the present invention.

Referring to FIG. 4, a gate metal layer is formed on a base substrate 110, and a first photo pattern PR1 is formed on the gate metal layer. The base substrate 110, may be formed of, for example, glass, quartz, ceramic, or silicon materials. Alternatively, the base substrate 110 may be formed of, for example, a flexible substrate such as a plastic substrate. Suitable materials for the flexible substrate include but are not limited to polyethersulfone (PES), polyethylenenaphthalate (PEN), polyethylene (PE), polyimide (PI), polyvinyl chloride (PVC), polyethylene terephthalate (PET), or combinations thereof. In addition, the base substrate 110 may be formed of, for example, transparent or opaque materials.

The gate metal layer includes, for example, a first titanium layer, a first copper layer formed on the first titanium layer and a second titanium layer formed on the first copper layer. The first titanium layer is formed under the first copper layer to increase an adhesive strength between the first copper layer and the base substrate 110. The second titanium layer is formed on the first copper layer to increase an etching property of the first copper layer. Alternatively, the first titanium layer may, for example, be omitted from the gate metal layer.

The gate metal layer is etched using the first photo pattern PR1 to form a gate pattern including, for example, a first titanium pattern, a first copper pattern and a second titanium pattern. The gate pattern includes, for example, a gate line GL as a first signal line and a gate electrode GE connected to the gate line GL.

The gate metal layer may be etched using an etching composition including, for example, about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water, so that the gate pattern including the first copper pattern having a taper angle equal to or greater than about 60° may be formed. For example, the first copper pattern of the gate pattern may be formed having a taper angle between about 60° and about 90°. A process forming the gate pattern is substantially the same as the method forming a metal pattern illustrated in FIG. 1 and FIG. 2, and thus any repetitive description will be omitted.

For example, referring to FIG. 5, a gate insulating layer 140, a semiconductive layer 152, an ohmic contact layer 154 and a source metal layer 160 are sequentially formed on the base substrate 110 on which the gate pattern is formed.

For example, the gate insulating layer 140 may include a silicon nitride (SiNx), silicon oxide (SiOx), silicon oxynitride (SiOxNy), aluminum oxide (AlOx), yttrium oxide (Y₂O₃), hafnium oxide (HfOx), zirconium oxide (ZrOx), aluminum nitride (AlN), aluminum oxynitride (AlNO), titanium oxide (TiOx), barium titanate (BaTiO3), lead titanate (PbTiO₃), or a combination thereof.

The gate insulating layer 140 may have a single layer structure. Alternatively, the gate insulating layer 140 may have a multi layer structure.

The semiconductive layer 152 may include, for example, amorphous silicon, polysilicon, micro-crystal silicon, single crystal silicon, or combinations thereof. In addition, the semiconductive layer 152 may have various shapes such as, for example, an island shape or a stripe shape.

The ohmic contact layer 154 may include, for example, amorphous silicon doped with n-type or p-type impurities. Alternatively, the ohmic contact layer 154 may include, for example, an oxide semiconductor layer. For example, the ohmic contact layer 154 may include an oxide semiconductor layer that includes one or more of the following elements: indium (In), gallium (Ga), zinc (Zn), tin (Sn), germanium (Ge), hafnium (Hf), and arsenide (As). For example, the ohmic contact layer 154 may include at least one of zinc oxide (ZnO), tin oxide (SnO₂), indium oxide (In₂O₃), zinc stannate (Zn₂SnO₄), gallium oxide (Ga₂O₃), or hafnium oxide (HfO₂) in the oxide semiconductor layer.

A photoresist layer 170 is formed on the source metal layer 160. The source metal layer 160 may include, for example, a third titanium layer, a second copper layer formed on the third titanium layer and a fourth titanium layer formed on the second copper layer. The fourth titanium layer is formed on the second copper layer to increase an etching property of the second copper layer. Alternatively, the third titanium layer may, for example, be omitted from the source metal layer 160.

Referring to FIG. 6, the photoresist layer 170 is exposed and developed to form a second photo pattern PR2. The second photo pattern PR2 may be formed using, for example, a mask including a light transmittance part transmitting a light, a light-blocking part blocking the light and a semi-transmittance part. The second photo pattern PR2 includes, for example, a first thickness portion having a first thickness d1 and a second thickness portion having a second thickness d2 smaller than the first thickness d1. The first thickness portion may have, for example, a thickness substantially the same as an initial thickness of the photoresist layer 170.

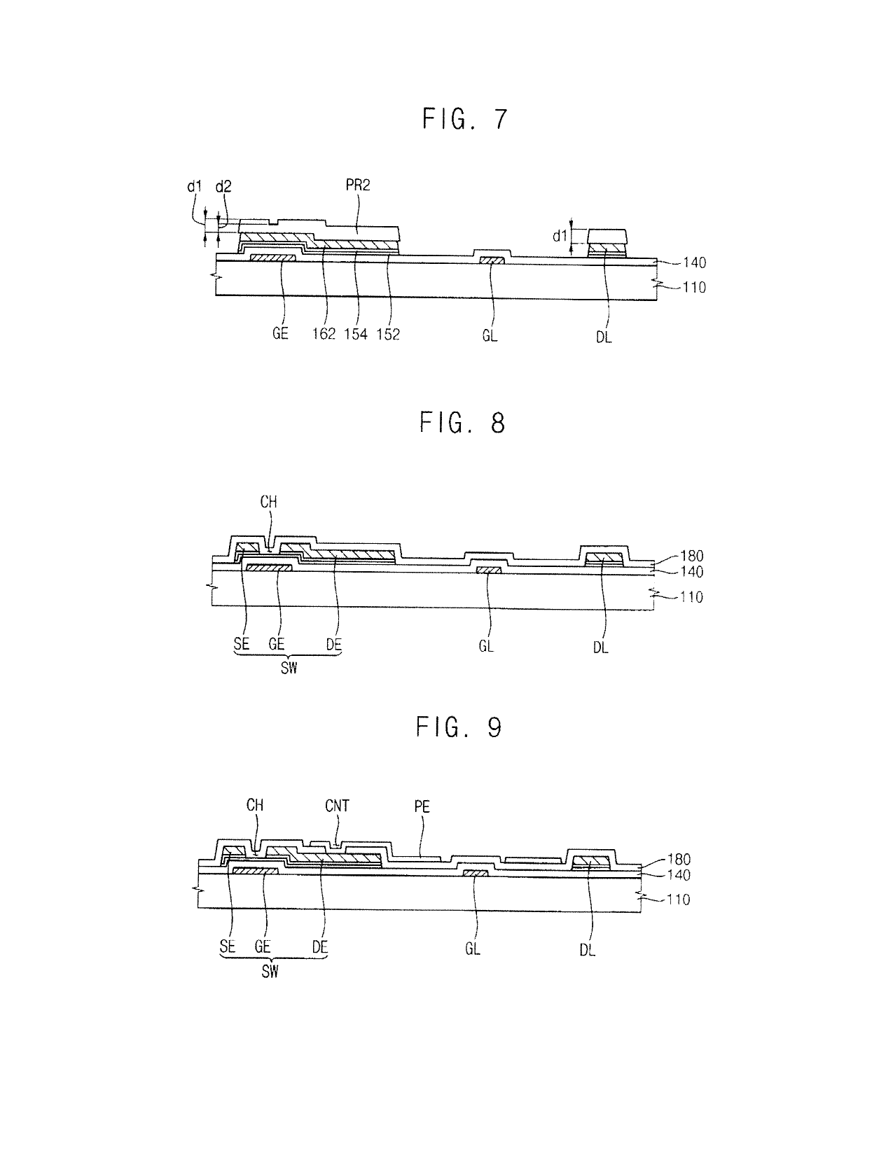

Referring to FIG. 7, a data line DL crossing the gate line GL and serving as a second signal line and a switching pattern 162 connected to the data line DL are formed using the second photo pattern PR2.

In an embodiment, the source metal layer may be etched using, for example, the same etching composition as described above for etching gate metal layer to form the data line DL and the switching pattern 162 including a second copper pattern having, for example, a taper angle equal to or greater than about 60°. For example, the second copper pattern may have a taper angle between about 60° and about 90°. A process forming the data line DL and the switching pattern 162 is substantially the same as the method of forming the gate pattern, and thus any repetitive description will be omitted.

Then, the ohmic contact layer 154 and the semiconductive layer 152 are etched using the second photo pattern PR2 and the switching pattern 162 as an etching stop layer.

Then, the second thickness of the second photo pattern PR2 is removed to form a residual pattern (not shown) thinner than the first thickness part. The switching pattern 162 is partially exposed by the residual pattern, and the switching pattern 162 may be etched using, for example, the same etching composition as described above and the residual pattern as an etching stop layer.

Referring to FIG. 8, the switching pattern 162 is etched using the residual pattern to form a source electrode SE connected to the data line DL and a drain electrode DE spaced apart from the source electrode SE. The source electrode SE, the drain electrode DE and the gate electrode GE form a thin-film transistor SW connected to the gate line GL and the data line DL. The switching pattern 162 exposed by the residual pattern is removed to form a channel region of the thin-film transistor SW.

Referring to FIG. 9, a passivation layer 180 is formed on the thin-film transistor SW including a channel CH. The channel CH may be defined by the source electrode SE and the drain electrode DE. After forming a contact hole CNT in the passivation layer 180, a pixel electrode PE is formed. The drain electrode DE is partially exposed though the contact hole CNT, and the pixel electrode PE makes contact with the drain electrode DE through the contact hole CNT to connect the thin-film transistor SW to the pixel electrode PE. For example, the passivation layer 180 may include an inorganic insulating material such as, for example, a silicon oxide (SiOx), a silicon nitride (SiNx) or a combination thereof.

Alternatively, the passivation layer 180 may include, for example, an organic insulating material such as benzocyclobutene (BCB), acryl-based resin or a combination thereof.

The pixel electrode PE may be formed of, for example, a transparent electric conductor, such as indium tin oxide (ITO) or indium zinc oxide (IZO), aluminum zinc oxide (AZO), cadmium tin oxide (CTO), or a reflective electric conductor such as aluminum (Al), gold (Au), silver (Ag), copper (Cu), iron (Fe), titanium (Ti), tantalum (Ta), molybdenum (Mo), rubidium (Rb), tungsten (W), and alloys, or combinations thereof. In addition, the pixel electrode PE can be formed of, for example, transflective materials or a combination of transparent materials and reflective materials.

According to the above descriptions, when the gate metal layer or the source metal layer is etched by the etching composition, the second titanium pattern disposed on the first copper pattern or the fourth titanium pattern disposed on the second copper pattern may prevent the first copper pattern or the second copper pattern from being etched to increase a taper angle of the first and second copper patterns. Therefore, a critical dimension of the first copper pattern or the second copper pattern may be increased to form a fine pattern.

According to an example embodiment of the present invention, a titanium layer is formed on a copper layer to control an etching degree of the copper layer. Thus, a copper pattern may have a taper angle equal to or greater than about 60° to form a fine metal pattern.

Having described example embodiments of the present invention, it is further noted that it is readily apparent to those of ordinary skill in the art that various modifications may be made without departing from the spirit and scope of the invention which is defined by the metes and bounds of the appended claims.

What is claimed is:

1. A method of forming a metal pattern, the method comprising:
sequentially forming a first titanium layer, a copper layer and a second titanium layer on a substrate;
forming a photo pattern on the second titanium layer; and
patterning the first titanium layer, the copper layer and the second titanium layer using the photo pattern to form a first titanium pattern, a copper pattern formed on the first titanium pattern and a second titanium pattern formed on the copper pattern.

2. The method of claim 1, wherein the copper layer has a thickness in a range between about 1 μm and about 3 μm.

3. The method of claim 1, wherein the first titanium layer, the copper layer and the second titanium layer are patterned using an etching composition,
wherein the etching composition includes about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water.

4. The method of claim 1, further comprising:
removing the photo pattern; and
washing the substrate on which the second titanium pattern, the copper pattern and the first titanium pattern are formed, using a cleaning solution including hydrogen fluoride (HF).

5. The method of claim 4, wherein the washing of the substrate using the cleaning solution removes edge portions of the second titanium pattern and the first titanium pattern which protrude beyond edge portions of the copper pattern.

6. The method of claim 1, wherein the copper pattern has a taper angle between about 60° and about 90°.

7. A method of manufacturing a display substrate, the method comprising:
sequentially forming a first titanium layer, a first copper layer and a second titanium layer on a base substrate;
forming a photo pattern on the second titanium layer;
patterning the first titanium layer, the first copper layer and the second titanium layer using the photo pattern, to form a first signal line including a first titanium pattern, a first copper pattern and a second titanium pattern;
forming a second signal line crossing the first signal line; and
forming a pixel electrode connected to a thin-film transistor which is connected to the first and second signal lines.

8. The method of claim 7, wherein the first copper layer has a thickness in a range between about 1 μm and about 3 μm.

9. The method of claim 7, wherein the first titanium layer, the first copper layer and the second titanium layer are patterned using an etching composition,
wherein the etching composition includes about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water.

10. The method of claim 7, further comprising:
removing the photo pattern; and
washing the first signal line using a cleaning solution including hydrogen fluoride (HF).

11. The method of claim 7, wherein the first copper pattern has a taper angle in a range between about 60° and about 90°.

12. The method of claim 7, wherein forming the second signal line comprises:
sequentially forming a third titanium layer, a second copper layer and a fourth titanium layer on the base substrate on which the first signal line is formed; and
patterning the third titanium layer, the second copper layer and the forth titanium layer to form the second signal line including a third titanium pattern, a second copper pattern and a fourth titanium pattern.

13. The method of claim 12, wherein the second copper layer has a thickness in a range between about 1 μm and about 3 μm.

14. The method of claim 12, wherein the second copper layer and the fourth titanium layer are etched using an etching composition,
wherein the etching composition includes about 0.1% by weight to about 30% by weight of ammonium persulfate, about 0.1% by weight to about 10% by weight of an inorganic acid, about 0.1% by weight to about 10% by weight of an acetate salt, about 0.01% by weight to about 5% by weight of a fluorine-containing compound, about 0.01% by weight to about 5% by weight of a sulfonic acid compound, about 0.01% by weight to about 2% by weight of an azole-based compound and a remainder of water.

15. The method of claim 12, further comprising:
washing the second signal line using a cleaning solution including hydrogen fluoride.

16. The method of claim 12, wherein the second copper pattern has a taper angle between about 60° and about 90°.

17. A method for manufacturing a display substrate, comprising:
forming a gate metal layer on a base substrate, wherein the gate metal layer includes a first metal layer including titanium disposed on the base substrate, a second metal layer including copper disposed on the first metal layer including titanium, and a third metal layer including titanium disposed on the second metal layer including copper;
forming a first photo pattern on the gate metal layer;
etching the gate metal layer using the first photo pattern to form a gate line and a gate electrode connected to the gate line, wherein the gate line and the gate electrode include a first metal pattern including titanium, a second metal pattern including copper and a third metal pattern including titanium;
sequentially forming a gate insulating layer, a semiconductive layer, an ohmic contact layer and a source metal layer on the base substrate on which the gate electrode and the gate line are formed, wherein the source metal layer includes a fourth metal layer including titanium, a fifth metal layer including copper formed on the fourth metal layer including titanium and a sixth metal layer including titanium formed on the fifth metal layer including copper;
forming a photoresist layer on the source metal layer;
exposing and developing the photoresist layer to form a second photo pattern on the source metal layer;
etching the source metal layer using the second photo pattern to form a data line crossing the gate line and a switching pattern connected to the data line, wherein the data line and the switching pattern include a fourth metal pattern including titanium, a fifth metal pattern including copper and a sixth metal pattern including titanium and wherein the etching of at least one of the gate metal layer or the source metal layer is performed using an etching composition which includes ammonium persulfate, an inorganic acid, an acetate salt, a fluorine-containing compound, a sulfonic acid compound, an azole-based compound and water,
etching the ohmic contact layer and the semiconductive layer using the second photo pattern and the switching pattern as an etching stop layer;
removing a portion of the second photo pattern to form a residual pattern; and
etching the switching pattern using the residual pattern to form a source electrode connected to the data line and a drain electrode spaced apart from the source electrode.

18. The method of claim 17, wherein the second metal pattern including copper and the fifth metal pattern including copper each have a taper angle between about 60° and about 90°.

19. The method of claim 17, wherein the gate metal layer or the source metal layer is etched using the etching composition, and wherein the etching composition includes the ammonium persulfate in an amount of about 0.1% by weight to about 30% by weight, the inorganic acid in an amount of about 0.1% by weight to about 10% by weight, the acetate salt in an amount of about 0.1% by weight to about 10% by weight, the fluorine-containing compound in an amount of about 0.01% by weight to about 5% by weight, the sulfonic acid in an amount of about 0.01% by weight to about 5% by weight, the azole-based compound in an amount of about 0.01% by weight to about 2% by weight and a remainder of water.
